(19) United States
(12) Patent Application Publication
(10) Pub. No.: US 2025/0349699 A1
(43) Pub. Date: Nov. 13, 2025

(54) WIRING SUBSTRATE AND SEMICONDUCTOR PACKAGE INCLUDING THE SAME

(71) Applicant: Samsung Electronics Co., Ltd., Suwon-si (KR)

(72) Inventors: In Lee, Suwon-si (KR); Dongok Kwak, Suwon-si (KR); Yeoung-Jun Cho, Suwon-si (KR); Donghun An, Suwon-si (KR)

(21) Appl. No.: 19/006,857

(22) Filed: Dec. 31, 2024

(30) Foreign Application Priority Data
May 13, 2024 (KR) 10-2024-0062758
Jul. 2, 2024 (KR) 10-2024-0087086

(51) Int. Cl. H01L 23/498

(52) U.S. Cl. CPC H01L 23/49838; H01L 23/49822

(57) ABSTRACT

A wiring substrate may include a first interconnection layer, a second interconnection layer thereon, and a substrate protection layer on a bottom surface of the first interconnection layer. The first interconnection layer may include a first under-bump pad, and a first wiring pattern that is connected to and extends from the first under-bump pad in a first direction. The second interconnection layer may include first and second via portions that are coupled to top surfaces of the first under-bump pad and the first wiring pattern, respectively, and a second wiring pattern that is on and is electrically connected to the first and second via portions. The substrate protection layer may have a first opening exposing a bottom surface of the first under-bump pad. The first via portion may vertically overlap with the first opening, and the second via portion may be horizontally spaced apart from the first opening.

### CROSS-REFERENCE TO RELATED APPLICATIONS

This U.S. non-provisional patent application claims priority under 35 U.S.C. § 119 to Korean Patent Application No. 10-2024-0062758 filed on May 13, 2024, and Korean Patent Application No. 10-2024-0087086 filed on Jul. 2, 2024, in the Korean Intellectual Property Office, the entire contents of which are hereby incorporated by reference.

### TECHNICAL FIELD

The present disclosure relates to a wiring substrate and a semiconductor package including the same.

### BACKGROUND

With advances in the electronics industry, demand for high-performance, high-speed, and compact electronic components is increasing. To meet demand, packaging technologies of mounting a plurality of semiconductor chips in a single package are being developed.

A semiconductor package may be configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With development of the electronics industry, semiconductor package technology is developing in various ways with the goals of miniaturization, weight reduction, and manufacturing cost reduction. Furthermore, as the utilization of this technology expands to different fields, including mass storage devices, several types of semiconductor packages are emerging.

### SUMMARY

An embodiment of the inventive concept provides a wiring substrate with improved structural stability and reliability, and a semiconductor package including the same.

An embodiment of the inventive concept provides a wiring substrate with improved electrical characteristics and a semiconductor package including the same.

According to an embodiment of the inventive concept, a wiring substrate may include a first interconnection layer, a second interconnection layer on the first interconnection layer, and a substrate protection layer on a bottom surface of the first interconnection layer opposite the second interconnection layer. The first interconnection layer may include a first under-bump pad, and a first wiring pattern that is electrically connected to the first under-bump pad and extends from the first under-bump pad in a first direction. The second interconnection layer may include a first via portion coupled to a top surface of the first under-bump pad and extending in a second direction that is perpendicular to the first direction, a second via portion coupled to a top surface of the first wiring pattern and extending in the second direction, and a second wiring pattern that is on the first and second via portions and is electrically connected to the first and second via portions. The substrate protection layer may have a first opening exposing a bottom surface of the first under-bump pad opposite the second interconnection layer. The first via portion may be overlap with the first opening in the second direction, and the second via portion may be laterally spaced apart from the first opening.

According to an embodiment of the inventive concept, a wiring substrate may include a first interconnection layer, a second interconnection layer on the first interconnection layer, and a substrate protection layer on a bottom surface of the first interconnection layer opposite the second interconnection layer. The first interconnection layer may include a first under-bump pad, a second under-bump pad laterally spaced apart from the first under-bump pad, and a first wiring pattern between the first under-bump pad and the second under-bump pad. The substrate protection layer may have a first opening exposing a bottom surface of the first under-bump pad opposite the second interconnection layer and a second opening exposing a bottom surface of the second under-bump pad opposite the second interconnection layer. The second interconnection layer may include a first via portion coupled to a top surface of the first under-bump pad, a second via portion adjacent to the first opening and coupled to a top surface of the first wiring pattern, a third via portion coupled to a top surface of the second under-bump pad, and a fourth via portion adjacent to the second opening and coupled to the top surface of the first wiring pattern. The first under-bump pad and the first wiring pattern may be electrically connected to each other through the first and second via portions, and the second under-bump pad and the first wiring pattern may be electrically connected to each other through the third and fourth via portions.

According to an embodiment of the inventive concept, a semiconductor package may include a substrate, a semiconductor chip on the substrate, and first and second outer terminals on a bottom surface of the substrate. The substrate may include a first under-bump pad and a second under-bump pad on the bottom surface of the substrate, a first wiring pattern on the bottom surface of the substrate that connects the first under-bump pad to the second under-bump pad, a second wiring pattern on the first under-bump pad and extending onto the first wiring pattern, a third wiring pattern on the second under-bump pad and extending onto the first wiring pattern, a first via portion and a second via portion extended from a bottom surface of the second wiring pattern, and a third via portion and a fourth via portion extending from a bottom surface of the third wiring pattern. The first outer terminal may be coupled to the first under-bump pad, and the second outer terminal may be coupled to the second under-bump pad. In plan view, the first via portion may overlap with the first outer terminal and may be coupled to the first under-bump pad, and the second via portion may be spaced apart from the first outer terminal and may be coupled to the first under-bump pad. In plan view, the he third via portion may overlap with the second outer terminal and may be coupled to the second under-bump pad, and the fourth via portion may be spaced apart from the second outer terminal and may be coupled to the second under-bump pad.

According to an embodiment of the inventive concept, a wiring substrate may include a first interconnection layer, a second interconnection layer on the first interconnection layer, a substrate protection layer on a bottom surface of the first interconnection layer opposite the second interconnection layer, and an outer terminal on the bottom surface of the first interconnection layer. The first interconnection layer may include an under-bump pad and a first wiring pattern connected to the under-bump pad and extending from the under-bump pad. The second interconnection layer may include a first via portion and a second via portion coupled to a top surface of the under-bump pad and a second wiring pattern on the first and second via portions and electrically connecting the first and second via portions to each other. The substrate protection layer may have an opening exposing a bottom surface of the under-bump pad. When viewed in a plan view, the opening may be inside a periphery of the under-bump pad, the first via portion may overlap with the opening, and the second via portion may be between an edge of the under-bump pad and the opening. The outer terminal may be coupled to the bottom surface of the under-bump pad in the opening, and the under-bump pad and the first wiring pattern may be electrically connected to each other through the first and second via portions..

### BRIEF DESCRIPTION OF THE DRAWINGS

FIG. 1 is a sectional view illustrating a wiring substrate according to an embodiment of the inventive concept.

FIG. 2 is a plan view illustrating a wiring substrate according to an embodiment of the inventive concept.

FIG. 3 is a sectional view illustrating a wiring substrate according to an embodiment of the inventive concept.

FIG. 4 is a plan view illustrating a wiring substrate according to an embodiment of the inventive concept.

FIG. 5 is a sectional view illustrating a wiring substrate according to an embodiment of the inventive concept.

FIGS. 6, 7, and 8 are plan views illustrating a wiring substrate according to an embodiment of the inventive concept.

FIG. 9 is a sectional view illustrating a wiring substrate according to an embodiment of the inventive concept.

FIGS. 10, 11, and 12 are plan views illustrating a wiring substrate according to an embodiment of the inventive concept.

FIG. 13 is a sectional view illustrating a wiring substrate according to an embodiment of the inventive concept.

FIG. 14 is a plan view illustrating a wiring substrate according to an embodiment of the inventive concept.

FIG. 15 is a sectional view illustrating a wiring substrate according to an embodiment of the inventive concept.

FIGS. 16 and 17 are plan views illustrating a wiring substrate according to an embodiment of the inventive concept.

FIGS. 18 and 19 are sectional views illustrating a semiconductor package according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

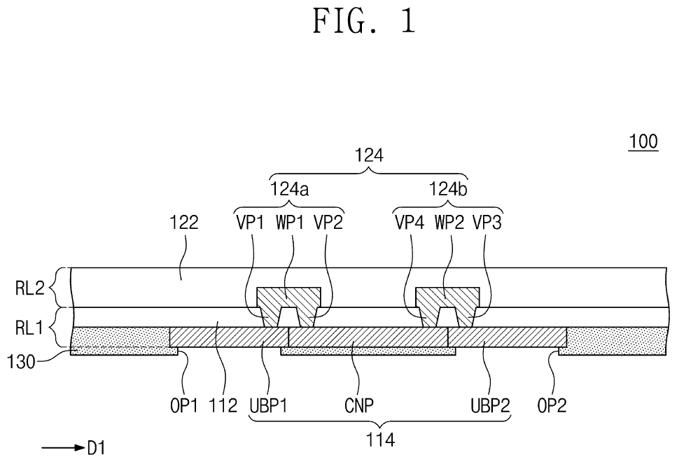

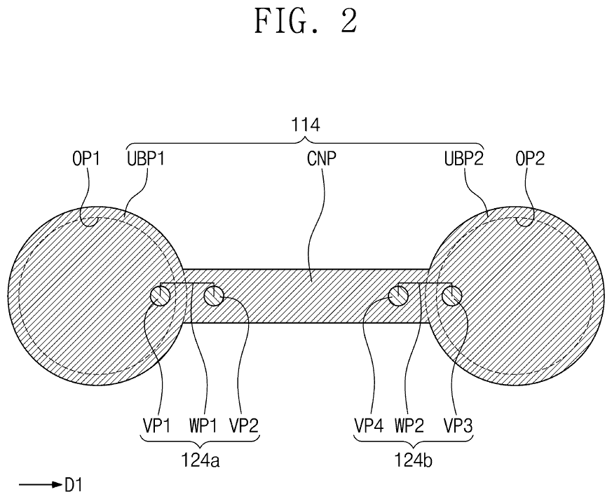

FIG. 1 is a sectional view illustrating a wiring substrate according to an embodiment of the inventive concept. FIG. 2 is a plan view illustrating a wiring substrate according to an embodiment of the inventive concept. For convenience in illustration, FIG. 2 schematically illustrates an electrical connection of a structure including a first wiring portion WP1 and a second wiring portion WP2.

Referring to FIGS. 1 and 2, a wiring substrate 100 may be provided. The wiring substrate 100 may be a redistribution substrate. For example, the wiring substrate 100 may include at least one substrate interconnection layer RL1 or RL2. The substrate interconnection layer may include substrate insulating patterns 112 and 122 and substrate wiring patterns 114 and 124 in the substrate insulating patterns 112 and 122. The wiring substrate 100 may further include a substrate protection layer 130. FIG. 1 illustrates an example, in which two substrate interconnection layers RL1 and RL2 are provided, but the inventive concept is not limited to this example.

A first substrate interconnection layer RL1 may correspond to an outer interconnection layer, to which outer terminals (e.g., solder balls) for mounting the wiring substrate 100 on an outer substrate or a motherboard are coupled. The first substrate interconnection layer RL1 may include a first substrate insulating pattern 112 and a first substrate wiring pattern 114.

The first substrate wiring pattern 114 may include a first under-bump pad UBP1, a second under-bump pad UBP2, and a connection pattern CNP.

The first and second under-bump pads UBP1 and UBP2 may be horizontally spaced apart from each other. The first and second under-bump pads UBP1 and UBP2 may have a plate or planar shape. The first and second under-bump pads UBP1 and UBP2 may have a circular shape, when viewed in a plan view of FIG. 2. However, the inventive concept is not limited to this example. In other embodiments, the first and second under-bump pads UBP1 and UBP2 may have various planar shapes (e.g., rectangular, polygonal, cross, and bar shapes). The first and second under-bump pads UBP1 and UBP2 may include a conductive material (e.g., copper (Cu), titanium (Ti), nickel (Ni), gold (Au), or alloys thereof).

The first and second under-bump pads UBP1 and UBP2 may be pads of the wiring substrate 100, to which an external power signal is applied. The first and second under-bump pads UBP1 and UBP2 may be electrically connected to each other to form a group of pads. That is, the first and second under-bump pads UBP1 and UBP2 may be pads, to which the same power signal is applied. The first and second under-bump pads UBP1 and UBP2 may be connected to each other by the connection pattern CNP.

The connection pattern CNP may be located between the first and second under-bump pads UBP1 and UBP2. The connection pattern CNP may be located at the same vertical level (i.e., in a vertical direction with reference to an upper or lower surface of the wiring substrate 100) as the first and second under-bump pads UBP1 and UBP2. For example, a top surface of the connection pattern CNP may be located at the same level as (i.e., coplanar with) a top surface of the first under-bump pad UBP1 and a top surface of the second under-bump pad UBP2. A bottom surface of the connection pattern CNP may be located at the same level as (i.e., coplanar with) a bottom surface of the first under-bump pad UBP1 and a bottom surface of the second under-bump pad UBP2. The connection pattern CNP may be directly connected to the first and second under-bump pads UBP1 and UBP2. For example, the connection pattern CNP may be used as a wiring pattern connecting the first and second under-bump pads UBP1 and UBP2. The connection pattern CNP may extend from the first under-bump pad UBP1 to the second under-bump pad UBP2 in a first direction D1, also referred to as a first horizontal or lateral direction. The connection pattern CNP may have a line or linear shape, when viewed in a plan view. FIG. 2 illustrates an example, in which the connection pattern CNP is linearly extended in the first direction D1, but the inventive concept is not limited to this example. The connection pattern CNP may have a bent or non-linear shape, when viewed in a plan view. The connection pattern CNP may include a conductive material (e.g., copper (Cu), titanium (Ti), nickel (Ni), gold (Au), or alloys thereof).

The first and second under-bump pads UBP1 and UBP2 and the connection pattern CNP may form a single object or a single conductive pattern, i.e., a unitary member. That is, the first and second under-bump pads UBP1 and UBP2 may correspond to pad portions of the single conductive pattern, and the connection pattern CNP may correspond to a wire portion of the single conductive pattern, which is used to connect the pad portions to each other, without a structural for visible interface therebetween. The first and second under-bump pads UBP1 and UBP2 and the connection pattern CNP may be conductive patterns, which are formed by patterning a conductive layer.

The first substrate insulating pattern 112 may be disposed on the first substrate wiring pattern 114. The first substrate insulating pattern 112 may cover the top surface of the first under-bump pad UBP1, the top surface of the second under-bump pad UBP2, and the top surface of the connection pattern CNP. That is, the first under-bump pad UBP1, the second under-bump pad UBP2, and the connection pattern CNP may be disposed on a bottom surface of the first substrate insulating pattern 112. The term “surround” or “cover” or “fill” as may be used herein may not require completely surrounding or covering or filling the described elements or layers, but may, for example, refer to partially surrounding or covering or filling the described elements or layers, for example, with voids or other discontinuities throughout. The first substrate insulating pattern 112 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers. In an embodiment, the first substrate insulating pattern 112 may include an insulating material. For example, the first substrate insulating pattern 112 may include silicon oxide (SiO), silicon nitride (SiN), silicon oxynitride (SiON), or an insulating polymer.

The substrate protection layer 130 may be disposed on a bottom surface of the first substrate interconnection layer RL1. The substrate protection layer 130 may cover the first under-bump pad UBP1, the second under-bump pad UBP2, and the connection pattern CNP, on the bottom surface of the first substrate insulating pattern 112. The substrate protection layer 130 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers. Alternatively, the substrate protection layer 130 may include an insulating polymer or an insulating material. In an embodiment, the substrate protection layer 130 may be formed of or include silicon oxide (SiO), silicon nitride (SiN), or silicon oxynitride (SiON).

The first substrate insulating pattern 112 may have a first opening OP1 and a second opening OP2.

The first opening OP1 may be provided below the first under-bump pad UBP1. Spatially relative terms such as “above,” “upper,” “top,” “below,” “lower,” “bottom,” “side,” and the like may refer to the drawings, except where otherwise indicated, but it will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The first opening OP1 may vertically penetrate the substrate protection layer 130 and may expose the bottom surface of the first under-bump pad UBP1. The term “expose” may be used to describe relationships between elements and/or certain intermediate processes in fabricating a completed semiconductor device, but may not necessarily require exposure of the particular region, layer, structure or other element in the context of the completed device. A planar or plan view area of the first opening OP1 may be smaller than a planar area of the first under-bump pad UBP1. A planar or plan view shape of the first opening OP1 may be similar to a planar shape of the first under-bump pad UBP1. In an embodiment, the planar shape of the first opening OP1 may be circular. When viewed in a plan view, the first opening OP1 may be placed in (e.g., confined within the planar or plan view area of) the first under-bump pad UBP1. When viewed in a plan view, the first opening OP1 may be spaced apart from an outer side surface of the first under-bump pad UBP1 in a direction toward an inner portion of the first under-bump pad UBP1. In other words, the substrate protection layer 130 may be provided to cover an edge portion of the bottom surface of the first under-bump pad UBP1 and to expose a center portion of the bottom surface of the first under-bump pad UBP1.

The second opening OP2 may be provided below the second under-bump pad UBP2. The second opening OP2 may vertically penetrate the substrate protection layer 130 and may expose the bottom surface of the second under-bump pad UBP2. A planar or plan view area of the second opening OP2 may be smaller than a planar area of the second under-bump pad UBP2. A planar or plan view shape of the second opening OP2 may be similar to a planar shape of the second under-bump pad UBP2. In an embodiment, the planar shape of the second opening OP2 may be circular. When viewed in a plan view, the second opening OP2 may be placed in (e.g., confined within the planar or plan view area of) the second under-bump pad UBP2. When viewed in a plan view, the second opening OP2 may be spaced apart from an outer side surface of the second under-bump pad UBP2 in a direction toward an inner portion of the second under-bump pad UBP2. In other words, the substrate protection layer 130 may be provided to cover an edge portion of the bottom surface of the second under-bump pad UBP2 and to expose a center portion of the bottom surface of the second under-bump pad UBP2.

A second substrate interconnection layer RL2 may be disposed on the first substrate interconnection layer RL1. The second substrate interconnection layer RL2 may be a wiring layer, in which internal wires of the wiring substrate 100 are provided, or a pad layer, which is used to mount a semiconductor chip, a semiconductor element, or a semiconductor device on the wiring substrate 100. The second substrate interconnection layer RL2 may include a second substrate insulating pattern 122 and a second substrate wiring pattern 124.

The second substrate wiring pattern 124 may be provided on the first substrate insulating pattern 112. The second substrate wiring pattern 124 may horizontally extend on the first substrate insulating pattern 112. The second substrate wiring pattern 124 may be provided on a top surface of the first substrate insulating pattern 112. The second substrate wiring pattern 124 may protrude to a region on the top surface of the first substrate insulating pattern 112. The second substrate wiring pattern 124 may include a conductive material. For example, the second substrate wiring pattern 124 may include a metallic material (e.g., copper (Cu)).

The second substrate wiring pattern 124 may have a first pattern 124a, which is adjacent to the first under-bump pad UBP1, and a second pattern 124b, which is adjacent to the second under-bump pad UBP2.

Each of the first and second patterns 124a and 124b may have a damascene structure. For example, the first pattern 124a may have the first wiring portion WP1, a first via portion VP1, and a second via portion VP2. The second pattern 124b may have the second wiring portion WP2, a third via portion VP3, and a fourth via portion VP4.

The first wiring portion WP1 and the second wiring portion WP2 may be located on the top surface of the first substrate insulating pattern 112. The first wiring portion WP1 and the second wiring portion WP2 may horizontally extend on the top surface of the first substrate insulating pattern 112.

The first and second via portions VP1 and VP2 may vertically penetrate the first substrate insulating pattern 112. The first and second via portions VP1 and VP2 may extend from a bottom surface of the first wiring portion WP1. The first and second via portions VP1 and VP2 may protrude from the bottom surface of the first wiring portion WP1 in a downward direction toward the substrate protection layer 130. The first via portion VP1 may vertically penetrate the first substrate insulating pattern 112 and may be coupled to the top surface of the first under-bump pad UBP1, and the second via portion VP2 may vertically penetrate the first substrate insulating pattern 112 and may be coupled to the top surface of the connection pattern CNP. In other words, the first via portion VP1 may be placed on and may contact the first under-bump pad UBP1, the second via portion VP2 may be placed on and may contact the connection pattern CNP, and the first wiring portion WP1 may extend from a region on the first under-bump pad UBP1 to a region on the connection pattern CNP to connect the first via portion VP1 to the second via portion VP2. That is, the first wiring portion WP1 may be a wiring pattern connecting the first and second via portions VP1 and VP2 to each other. The first via portion VP1 may be vertically overlapped with the first opening OP1. Components or layers described with reference to “overlap” in a particular direction may be at least partially obstructed by one another when viewed along a line extending in the particular direction or in a plane perpendicular to the particular direction. The second via portion VP2 may be laterally spaced apart from the first opening OP1, when viewed in a plan view. The first via portion VP1 may be placed to be close to (e.g., offset toward) the connection pattern CNP, based on or relative to a center of the first under-bump pad UBP1.

The first and second via portions VP1 and VP2 and the first wiring portion WP1 may form a single object or unitary member. That is, the first wiring portion WP1, which is placed on the first substrate insulating pattern 112, may be a head portion, which is used as a horizontal wire, and the first and second via portions VP1 and VP2 may be tail portions. When viewed in a sectional view, the first pattern 124a may have a shape resembling the Greek letter “π” or “π”.

The third and fourth via portions VP3 and VP4 may vertically penetrate the first substrate insulating pattern 112. The third and fourth via portions VP3 and VP4 may extend from a bottom surface of the second wiring portion WP2. The third and fourth via portions VP3 and VP4 may protrude from the bottom surface of the second wiring portion WP2 in a downward direction. The third via portion VP3 may vertically penetrate the first substrate insulating pattern 112 and may be coupled to the top surface of the second under-bump pad UBP2, and the fourth via portion VP4 may vertically penetrate the first substrate insulating pattern 112 and may be coupled to the top surface of the connection pattern CNP. In other words, the third via portion VP3 may be placed on and may contact the second under-bump pad UBP2, the fourth via portion VP4 may be placed on and may contact the connection pattern CNP, and the second wiring portion WP2 may extend from a region on the second under-bump pad UBP2 to a region on the connection pattern CNP to connect the third via portion VP3 to the fourth via portion VP4. That is, the second wiring portion WP2 may be a wiring pattern connecting the third and fourth via portions VP3 and VP4. The third via portion VP3 may be vertically overlapped with the second opening OP2. The fourth via portion VP4 may be laterally spaced apart from the second opening OP2, when viewed in a plan view. The third via portion VP3 may be placed to be close to (e.g., offset toward) the connection pattern CNP, based on or relative to a center of the second under-bump pad UBP2.

The third and fourth via portions VP3 and VP4 and the second wiring portion WP2 may form a single object or unitary member. That is, the second wiring portion WP2, which is placed on the first substrate insulating pattern 112, may be a head portion, which is used as a horizontal wire, and the third and fourth via portions VP3 and VP4 may be tail portions. When viewed in a sectional view, the second pattern 124b may have a shape resembling the Greek letter “π” or “π”.

The second substrate insulating pattern 122 may be disposed on the first substrate insulating pattern 112. The second substrate insulating pattern 122 may cover the second substrate wiring pattern 124, on the top surface of the first substrate insulating pattern 112. In detail, the second substrate insulating pattern 122 may cover the first wiring portion WP1 and the second wiring portion WP2, which are placed on the top surface of the first substrate insulating pattern 112. The second substrate insulating pattern 122 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers. Alternatively, the second substrate insulating pattern 122 may include an insulating material. For example, the second substrate insulating pattern 122 may include silicon oxide (SiO), silicon nitride (SiN), silicon oxynitride (SiON), or an insulating polymer.

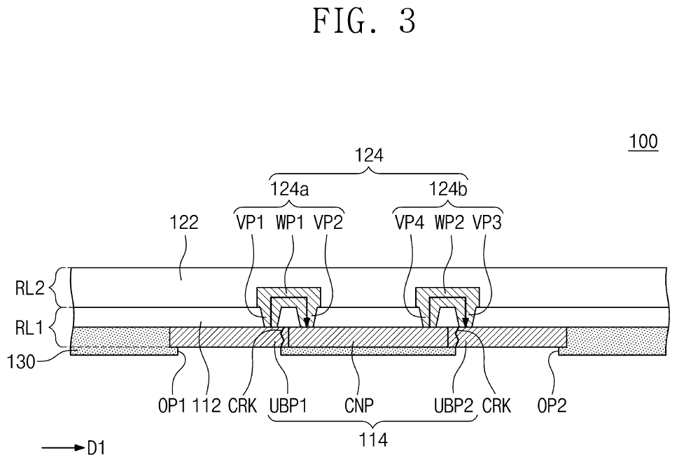

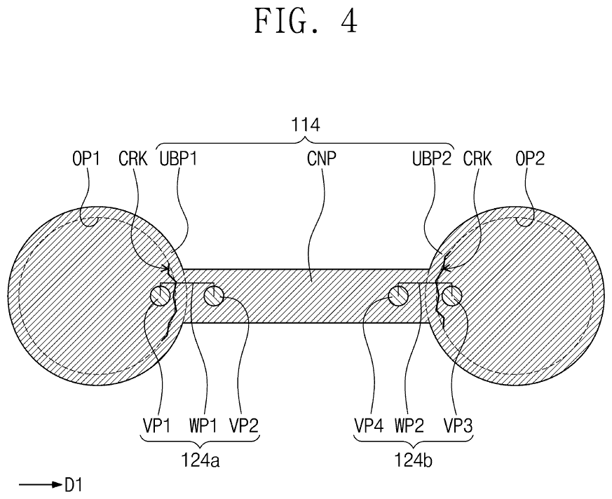

The first and second openings OP1 and OP2 may be provided in the substrate protection layer 130 covering the first and second under-bump pads UBP1 and UBP2 to allow outer terminals (e.g., solder balls) of the wiring substrate 100 to be coupled to the first and second under-bump pads UBP1 and UBP2. Here, in the first and second under-bump pads UBP1 and UBP2, a pressure exerted on a portion covered with the substrate protection layer 130 may be different from that on another portion that is not covered with the substrate protection layer 130. This may lead to a damage (such as cracking) of the first and second under-bump pads UBP1 and UBP2. This will be described in more detail with reference to FIGS. 3 and 4.

FIG. 3 is a sectional view illustrating a wiring substrate according to an embodiment of the inventive concept. FIG. 4 is a plan view illustrating a wiring substrate according to an embodiment of the inventive concept.

Referring to FIGS. 3 and 4, due to a difference in pressure exerted on the portions covered and not covered with the substrate protection layer 130, a crack CRK may be formed in the first and/or second under-bump pads UBP1 and UBP2, as described above. When viewed in a plan view, the crack CRK may be formed along an inner side surface of the first opening OP1 in the first under-bump pad UBP1 and/or may be formed along an inner side surface of the second opening OP2 in the second under-bump pad UBP2, that is, between inner and outer portions of the pads UBP1 and/or UBP2. FIGS. 3 and 4 illustrate an example, in which the crack CRK is formed in only respective regions adjacent to the connection pattern CNP, but the inventive concept is not limited to this example. The crack CRK may deteriorate an electrical connection between the first under-bump pad UBP1 and the connection pattern CNP or an electrical connection between the connection pattern CNP and the second under-bump pad UBP2.

According to an embodiment of the inventive concept, the first pattern 124a of the second substrate interconnection layer RL2 may be used as a bypass (depicted by the arrow in FIG. 3) for an electrical connection between the first under-bump pad UBP1 and the connection pattern CNP, and the second pattern 124b of the second substrate interconnection layer RL2 may be used as a bypass (depicted by the arrow in FIG. 3) for an electrical connection between the second under-bump pad UBP2 and the connection pattern CNP. Thus, even when the crack CRK or a damage issue occurs in the first and second under-bump pads UBP1 and UBP2 depending on the positions of the substrate protection layer 130 and the first and second openings OP1 and OP2, the first and second patterns 124a and 124b may be used to stably maintain the electrical connection between the first and second under-bump pads UBP1 and UBP2 and the connection pattern CNP. That is, it may be possible to provide a wiring substrate with improved structural stability, reliability, and electrical characteristics.

In addition, the first and second via portions VP1 and VP2 of the first pattern 124a may be placed to be adjacent to a boundary between the first under-bump pad UBP1 and the connection pattern CNP, and the third and fourth via portions VP3 and VP4 of the second pattern 124b may be placed to be adjacent to a boundary between the second under-bump pad UBP2 and the connection pattern CNP. In other words, an electrical path between the first under-bump pad UBP1 and the connection pattern CNP through the first pattern 124a may have a reduced length, and an electrical path between the second under-bump pad UBP2 and the connection pattern CNP through the second pattern 124b may have a reduced length.

Hereinafter, an element previously described with reference to FIGS. 1 to 4 may be identified by the same reference number without repeating an overlapping or similar description thereof, for brevity. That is, technical features, which are different from those in the embodiments of FIGS. 1 to 4, will be mainly described below.

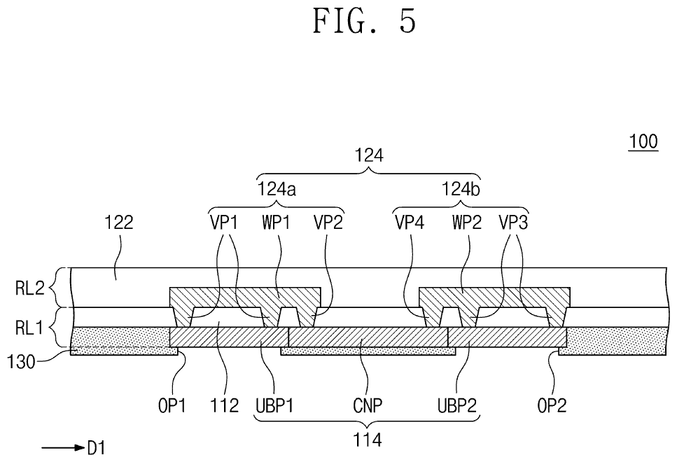

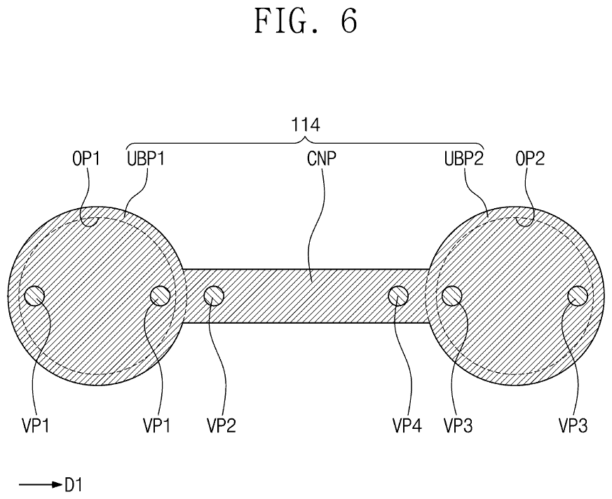

FIG. 5 is a sectional view illustrating a wiring substrate according to an embodiment of the inventive concept. FIGS. 6 to 8 are plan views illustrating a wiring substrate according to an embodiment of the inventive concept. For convenience in illustration, the electrical connection between the first via portions VP1 and the second via portion VP2 by the first wiring portion WP1 and the electrical connection between the third via portions VP3 and the fourth via portion VP4 by the second wiring portion WP2 are not illustrated in FIGS. 6 to 8.

Referring to FIGS. 5 and 6, the first via portion VP1 of the first pattern 124a may be provided in plural. That is, the first pattern 124a may include multiple first via portions VP1. The first via portions VP1 may be inside the first opening OP1, when viewed in a plan view.

One of the first via portions VP1 may be disposed to be adjacent to the connection pattern CNP. That is, the above one of the first via portions VP1 may be placed at a position that is spaced apart or offset from the center of the first under-bump pad UBP1 in the first direction D1. Another one of the first via portions VP1 may be arranged symmetrically to the above one of the first via portions VP1 with respect to the center of the first under-bump pad UBP1. For example, the another one of the first via portions VP1 may be placed at a position, which is spaced apart or offset from the center of the first under-bump pad UBP1 in an opposite direction of the first direction D1. The first via portions VP1 may be arranged in the first direction D1 or in a line shape.

The first wiring portion WP1 may connect the first via portions VP1 to the second via portion VP2. The first wiring portion WP1 may extend from a top surface of the second via portion VP2 to top surfaces of the first via portions VP1.

The third via portion VP3 of the second pattern 124b may be provided in plural. That is, the second pattern 124b may include multiple third via portions VP3. The third via portions VP3 may be inside the second opening OP2, when viewed in a plan view.

One of the third via portions VP3 may be disposed to be adjacent to the connection pattern CNP. That is, the above one of the third via portions VP3 may be placed at a position, which is spaced apart or offset from the center of the second under-bump pad UBP2 in an opposite direction of the first direction D1. Another one of the third via portions VP3 may be arranged symmetrically to the above one of the third via portions VP3 with respect to the center of the second under-bump pad UBP2. For example, the another one of the third via portions VP3 may be placed at a position, which is spaced apart or offset from the center of the second under-bump pad UBP2 in the first direction D1. The third via portions VP3 may be arranged in the first direction D1 or in a line shape.

The second wiring portion WP2 may connect the third via portions VP3 to the fourth via portion VP4. The second wiring portion WP2 may extend from a top surface of the fourth via portion VP4 to top surfaces of the third via portions VP3.

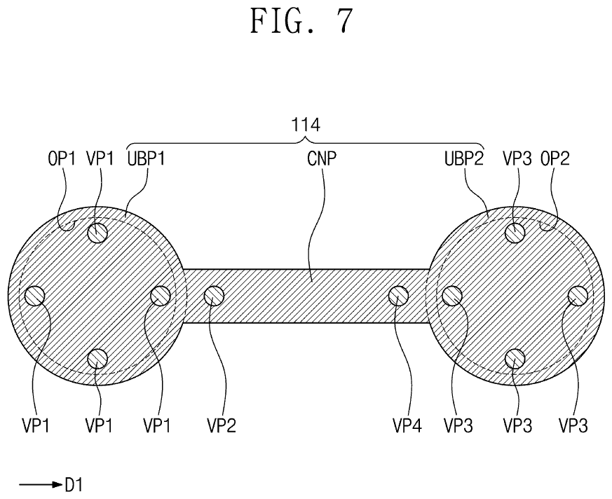

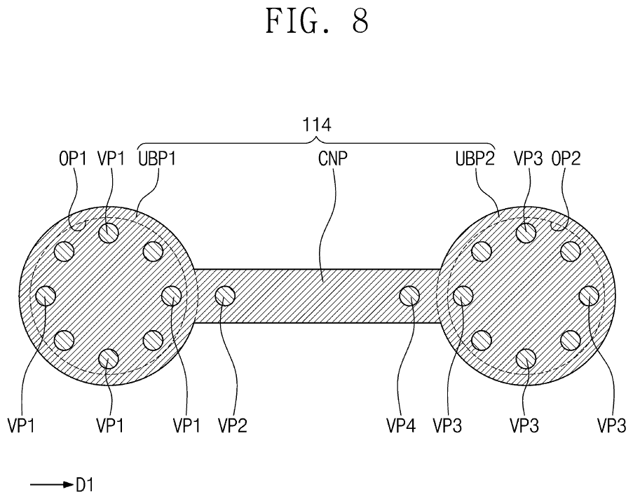

FIG. 6 illustrates an example, in which a pair of the first via portions VP1 and a pair of the third via portions VP3 are provided, but the inventive concept is not limited to this example. The number of the first via portions VP1 and the number of the third via portions VP3 may be four, as shown in FIG. 7, or may be eight, as shown in FIG. 8. Alternatively, the number of the first via portions VP1 and the number of the third via portions VP3 may be different from those in the illustrated structure. Here, the first via portions VP1 may be disposed symmetrically with respect to the center of the first under-bump pad UBP1. For example, the first via portions VP1 may be arranged along an inner side surface of the first opening OP1. In other words, the first via portions VP1 may be arranged in a ring shape, on the first under-bump pad UBP1. Adjacent ones of the first via portions VP1 may be spaced apart from each other (or from a center of the first under-bump pad UBP1) by the same distance. The third via portions VP3 may be disposed symmetrically with respect to the center of the second under-bump pad UBP2. For example, the third via portions VP3 may be arranged along an inner side surface of the second opening OP2. In other words, the third via portions VP3 may be arranged in a ring shape, on the second under-bump pad UBP2. Adjacent ones of the third via portions VP3 may be spaced apart from each other (or from a center of the second under-bump pad UBP2) by the same distance.

According to an embodiment of the inventive concept, a plurality of first via portions VP1 may be provided to overlap with the first under-bump pad UBP1 (e.g., in a vertical direction), and a plurality of third via portions VP3 may be provided to overlap with the second under-bump pad UBP2 (e.g., in a vertical direction). By using the first pattern 124a of the second substrate interconnection layer RL2, it may be possible to increase the number of available bypass paths for electrical connection between the first under-bump pad UBP1 and the connection pattern CNP, and by using the second pattern 124b of the second substrate interconnection layer RL2, it may be possible to increase the number of available bypass paths for electrical connection between the second under-bump pad UBP2 and the connection pattern CNP. Thus, it may be possible to construct stable electrical connections between the first and second under-bump pads UBP1 and UBP2 and the connection pattern CNP.

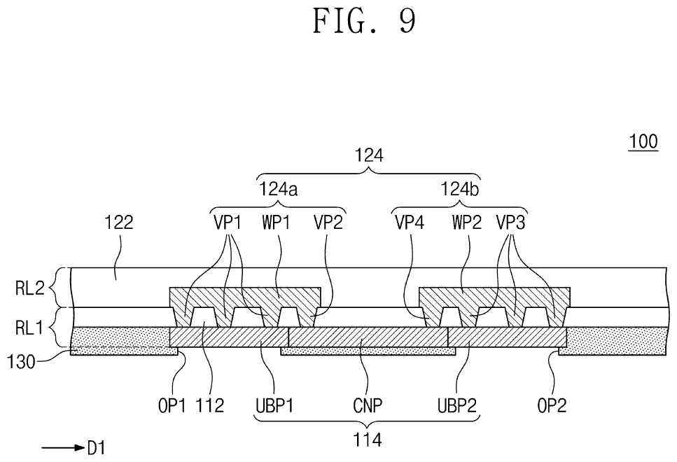

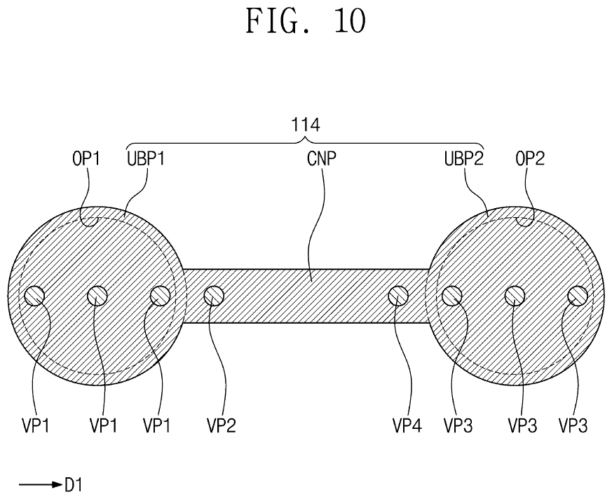

FIG. 9 is a sectional view illustrating a wiring substrate according to an embodiment of the inventive concept. FIGS. 10 to 12 are plan views illustrating a wiring substrate according to an embodiment of the inventive concept. For convenience in illustration, the electrical connection between the first via portions VP1 and the second via portion VP2 by the first wiring portion WP1 and the electrical connection between the third via portions VP3 and the fourth via portion VP4 by the second wiring portion WP2 are not illustrated in FIGS. 10 to 12.

Referring to FIGS. 9 and 10, the first via portion VP1 of the first pattern 124a may be provided in plural (i.e., with multiple first via portions VP1). The first via portions VP1 may be inside the first opening OP1, when viewed in a plan view.

The first via portions VP1 may be arranged in the first direction D1 and in a line shape. For example, one of the first via portions VP1 may be placed on or adjacent the center of the first under-bump pad UBP1. The first via portions VP1 may further include two portions, which are opposite to each other with the above one of the first via portions VP1 interposed therebetween, and one of which is laterally between the above one of the first via portions VP1 and the connection pattern CNP, e.g., in or along the first direction D1.

The first wiring portion WP1 may connect the first via portions VP1 to the second via portion VP2. The first wiring portion WP1 may extend from the top surface of the second via portion VP2 to the top surfaces of the first via portions VP1.

The third via portion VP3 of the second pattern 124b may be provided in plural (i.e., with multiple third via portions VP3). The third via portions VP3 may be inside the second opening OP2, when viewed in a plan view.

The third via portions VP3 may be arranged in the first direction D1 and in a line shape. For example, one of the third via portions VP3 may be placed on or adjacent the center of the second under-bump pad UBP2. The third via portions VP3 may further include two portions, which are opposite to each other with the above one of the third via portions VP3 interposed therebetween, and one of which is laterally between the above one of the third via portions VP3 and the connection pattern CNP, e.g., in or along the first direction D1.

The second wiring portion WP2 may connect the third via portions VP3 to the fourth via portion VP4. The second wiring portion WP2 may extend from the top surface of the fourth via portion VP4 to the top surfaces of the third via portions VP3.

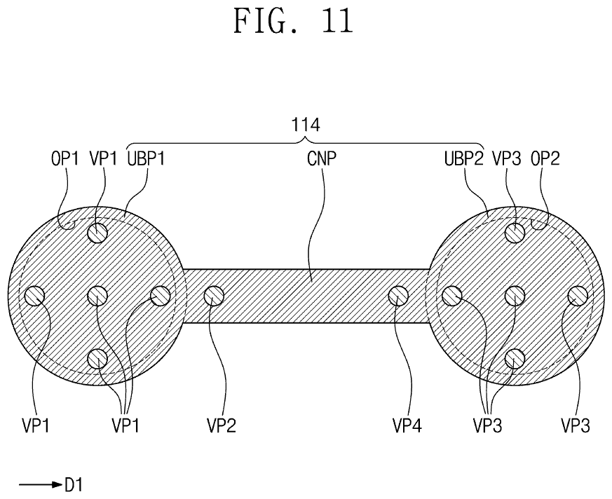

Unlike this, one of the first via portions VP1 may be placed on or adjacent the center of the first under-bump pad UBP1, remaining four of the first via portions VP1 may be arranged along the inner side surface of the first opening OP1, as shown in FIG. 11. In other words, the first via portions VP1 may be arranged in a cross shape, with the intersection of the cross placed on or adjacent the center of the first under-bump pad UBP1 in plan view. One of the third via portions VP3 may be placed on or adjacent the center of the second under-bump pad UBP2, and remaining four of the third via portions VP3 may be arranged along the inner side surface of the second opening OP2. That is, the third via portions VP3 may be arranged in a cross shape, with the intersection of the cross placed on or adjacent the center of the second under-bump pad UBP2 in plan view.

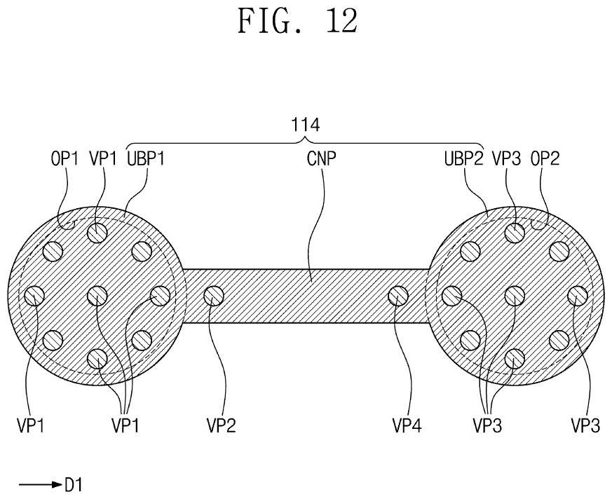

Alternatively, as shown in FIG. 12, one of the first via portions VP1 may be placed on or adjacent the center of the first under-bump pad UBP1, remaining eight of the first via portions VP1 may be arranged along the inner side surface of the first opening OP1. One of the third via portions VP3 may be placed on or adjacent the center of the second under-bump pad UBP2, and remaining eight of the third via portions VP3 may be arranged along the inner side surface of the second opening OP2.

However, the inventive concept is not limited to these examples, and the number and arrangement of the first via portions VP1 and the number and arrangement of the third via portions VP3 may be variously changed.

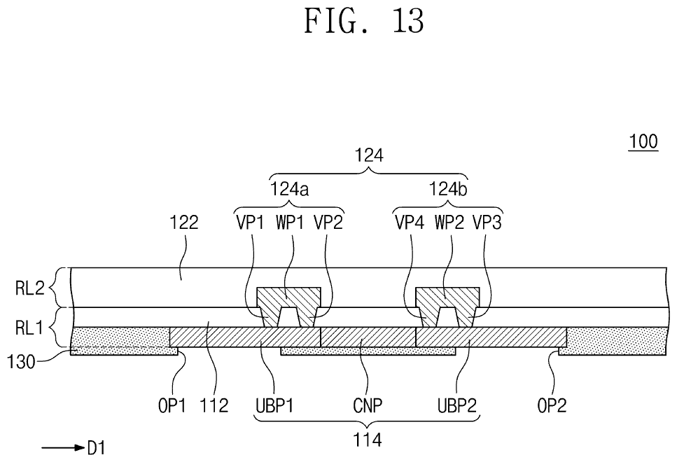

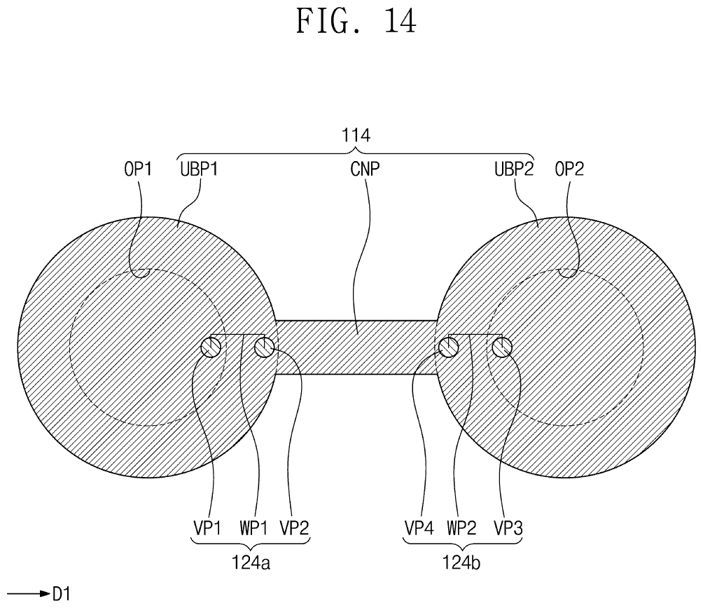

FIG. 13 is a sectional view illustrating a wiring substrate according to an embodiment of the inventive concept. FIG. 14 is a plan view illustrating a wiring substrate according to an embodiment of the inventive concept. For convenience in illustration, FIG. 14 schematically illustrates an electrical connection of a structure including the first wiring portion WP1 and the second wiring portion WP2.

Referring to FIGS. 13 and 14, unlike the embodiments of FIGS. 1 to 12, (up to an entirety of) the first pattern 124a may be placed on the first under-bump pad UBP1, and (up to an entirety of) the second pattern 124b may be placed on the second under-bump pad UBP2. That is, the first sand second patterns 124a and 124b may completely overlap with the first and second under-bump pads UBP1 and UBP2, respectively, in the vertical direction.

The first and second via portions VP1 and VP2 may extend from the bottom surface of the first wiring portion WP1. The first and second via portions VP1 and VP2 may vertically penetrate the first substrate insulating pattern 112 and may be coupled to the top surface of the first under-bump pad UBP1. In other words, both the first and second via portions VP1 and VP2 may be on the first under-bump pad UBP1. The first via portion VP1 may be vertically overlapped with the first opening OP1. The second via portion VP2 may be laterally spaced apart from an edge of the first opening OP1, when viewed in a plan view. That is, both the first and second via portions VP1 and VP2 may be placed on the first under-bump pad UBP1, the first via portion VP1 may be placed inside the first opening OP1, and the second via portion VP2 may be placed outside the first opening OP1. The second via portion VP2 may be placed between the first opening OP1 and an outer side surface or edge of the first under-bump pad UBP1. The first wiring portion WP1 may connect the first and second via portions VP1 and VP2 to each other, on the first under-bump pad UBP1.

The third and fourth via portions VP3 and VP4 may extend from the bottom surface of the second wiring portion WP2. The third and fourth via portions VP3 and VP4 may vertically penetrate the first substrate insulating pattern 112 and may be coupled to the top surface of the second under-bump pad UBP2. In other words, both the third and fourth via portions VP3 and VP4 may be on the second under-bump pad UBP2. The third via portion VP3 may be vertically overlapped with the second opening OP2. The fourth via portion VP4 may be laterally spaced apart from an edge of the second opening OP2, when viewed in a plan view. In other words, both the third and fourth via portions VP3 and VP4 may be placed on the second under-bump pad UBP2, the third via portion VP3 may be placed inside the second opening OP2, and the fourth via portion VP4 may be placed outside the second opening OP2. The fourth via portion VP4 may be placed between the second opening OP2 and an outer side surface or edge of the second under-bump pad UBP2. The second wiring portion WP2 may connect the third and fourth via portions VP3 and VP4 to each other, on the second under-bump pad UBP2.

According to an embodiment of the inventive concept, two regions, which are separated from each other with a vulnerable point in the first under-bump pad UBP1 interposed therebetween, may be electrically connected to each other using the first pattern 124a of the second substrate interconnection layer RL2. That is, a bypass may be provided for an electrical connection between the first under-bump pad UBP1 and the connection pattern CNP. Two regions, which are separated from each other with a vulnerable point in the second under-bump pad UBP2 interposed therebetween, may be electrically connected to each other using the second pattern 124b of the second substrate interconnection layer RL2. That is, a bypass may be provided for an electrical connection between the second under-bump pad UBP2 and the connection pattern CNP. Thus, even when the first and second under-bump pads UBP1 and UBP2 are damaged depending on positions of the substrate protection layer 130 and the first and second openings OP1 and OP2, an electric disconnection issue may not occur in the first and second under-bump pads UBP1 and UBP2. That is, it may be possible to provide a wiring substrate with improved structural stability, reliability, and electrical characteristics.

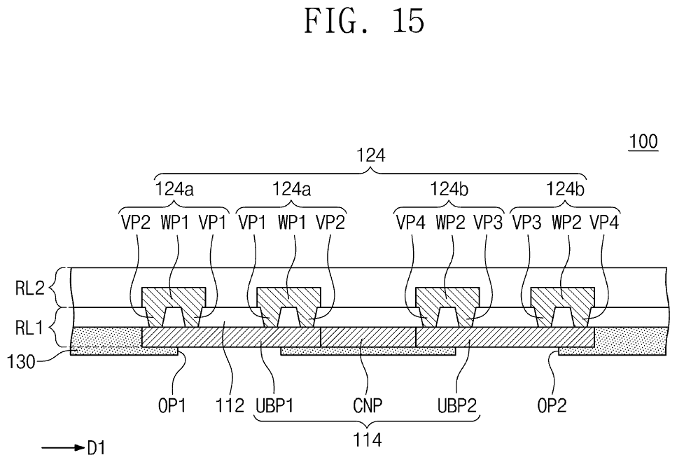

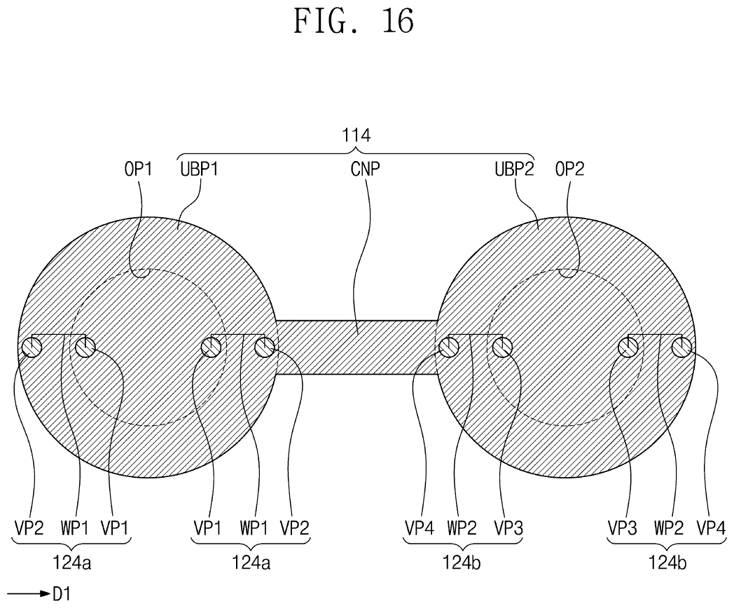

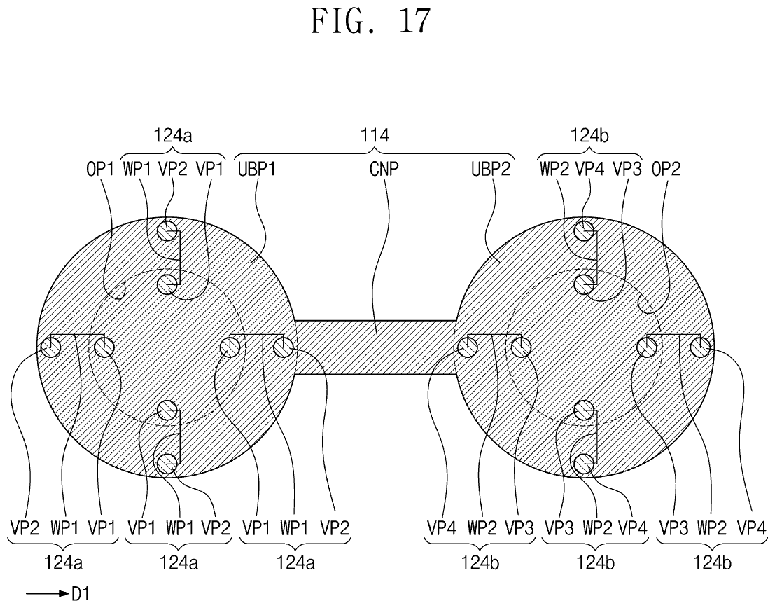

FIG. 15 is a sectional view illustrating a wiring substrate according to an embodiment of the inventive concept. FIGS. 16 and 17 are plan views illustrating a wiring substrate according to an embodiment of the inventive concept.

Referring to FIGS. 15 and 16, the first pattern 124a may be provided in plural (i.e., multiple first patterns 124a). The first patterns 124a may be disposed symmetrically with respect to the center of the first under-bump pad UBP1. For example, as shown in FIG. 16, one of the first patterns 124a may be disposed to be adjacent to the connection pattern CNP. In other words, the above one of the first patterns 124a may be placed at a position that is laterally spaced apart from the center of the first under-bump pad UBP1 in the first direction D1. Another one of the first patterns 124a may be placed symmetrically to the above one of the first patterns 124a with respect to the center of the first under-bump pad UBP1. For example, the another one of the first patterns 124a may be placed at a position, which is laterally spaced apart from the center of the first under-bump pad UBP1 in an opposite direction of the first direction D1. In other embodiments, as shown in FIG. 17, the first patterns 124a may be arranged along the inner side surface of the first opening OP1. In other words, the first patterns 124a may be arranged in a ring shape, on the first under-bump pad UBP1.

The first patterns 124a may not be directly connected to each other. For example, the first patterns 124a may be spaced apart from each other, and the first wiring portions WP1 of the first patterns 124a may not be connected to each other. Alternatively, the first wiring portions WP1 of the first patterns 124a may extend to a region on or adjacent the center of the first under-bump pad UBP1 and may be connected to each other.

The second pattern 124b may be provided in plural (i.e., multiple second patterns 124b). The second patterns 124b may be disposed symmetrically with respect to the center of the second under-bump pad UBP2. For example, as shown in FIG. 16, one of the second patterns 124b may be disposed to be adjacent to the connection pattern CNP. That is, the above one of the second patterns 124b may be placed at a position that is laterally spaced apart from the center of the second under-bump pad UBP2 in the direction opposite to the first direction D1. Another one of the second patterns 124b may be placed symmetrically to the above one of the second patterns 124b with respect to the center of the second under-bump pad UBP2. For example, the another one of the second patterns 124b may be placed at a position, which is laterally spaced apart from the center of the second under-bump pad UBP2 in the first direction D1. In other embodiments, as shown in FIG. 17, the second patterns 124b may be arranged along the inner side surface of the second opening OP2. That is, the second patterns 124b may be arranged in a ring shape, on the second under-bump pad UBP2.

The second patterns 124b may not be directly connected to each other. For example, the second patterns 124b may be spaced apart from each other, and the second wiring portions WP2 of the second patterns 124b may not be connected to each other. Alternatively, the second wiring portions WP2 of the second patterns 124b may extend to a region on or adjacent the center of the second under-bump pad UBP2 and may be connected to each other.

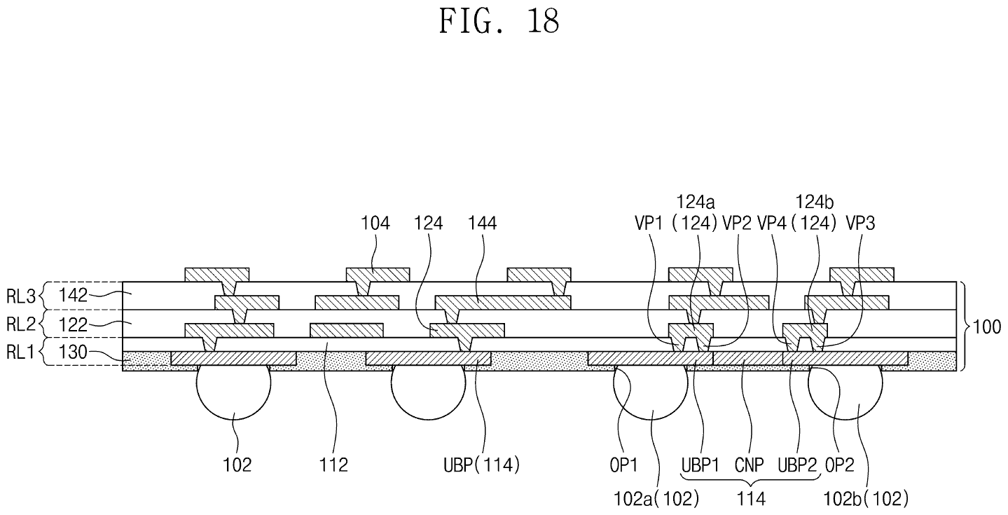

FIG. 18 is a sectional view illustrating a semiconductor package according to an embodiment of the inventive concept.

Referring to FIG. 18, the wiring substrate 100 may include at least one substrate interconnection layer RL1, RL2, or RL3.

The first substrate interconnection layer RL1 may include the first substrate insulating pattern 112 and the first substrate wiring pattern 114.

The first substrate wiring pattern 114 may further include at least one third under-bump pad UBP. The first and second under-bump pads UBP1 and UBP2 may be pads of the wiring substrate 100, which are used to receive a power signal from the outside. The third under-bump pad UBP may be pads of the wiring substrate 100, which are used to receive data signals from the outside. In the case where a plurality of third under-bump pads UBP3 are provided, the third under-bump pads UBP may not be electrically connected to each other, in the wiring substrate 100. That is, the third under-bump pads UBP may be pads, which are used to transmit different signals from each other.

Outer connection terminals 102 may be provided below the first substrate interconnection layer RL1. The outer connection terminals 102 may be coupled to bottom surfaces of the first to third under-bump pads UBP1, UBP2, and UBP through the openings, which are formed in the substrate protection layer 130.

The second substrate interconnection layer RL2 may include the second substrate insulating pattern 122 and the second substrate wiring pattern 124.

At least a portion of the second substrate wiring pattern 124 may have the first pattern 124a and the second pattern 124b.

The first and second via portions VP1 and VP2 of the first pattern 124a may vertically penetrate the first substrate insulating pattern 112 and may be coupled to the top surface of the first under-bump pad UBP1. Here, the first via portion VP1 may be placed over an outer connection terminal 102a (hereinafter, a first outer connection terminal) coupled to the first under-bump pad UBP1. That is, the first via portion VP1 may be vertically overlapped with the first outer connection terminal 102a. The second via portion VP2 may be placed at a side of the first outer connection terminal 102a. The second via portion VP2 may be laterally spaced apart from the first outer connection terminal 102a, when viewed in a plan view.

The third and fourth via portions VP3 and VP4 of the second pattern 124b may vertically penetrate the first substrate insulating pattern 112 and may be coupled to the top surface of the second under-bump pad UBP2. Here, the third via portion VP3 may be placed over an outer connection terminal 102b (hereinafter, a second outer connection terminal) coupled to the second under-bump pad UBP2. That is, the third via portion VP3 may be vertically overlapped with the second outer connection terminal 102b. The fourth via portion VP4 may be placed at a side of the second outer connection terminal 102b. The fourth via portion VP4 may be laterally spaced apart from the second outer connection terminal 102b, when viewed in a plan view.

The outer connection terminals 102 may be attached to the wiring substrate 100, or the wiring substrate 100 attached with the outer connection terminals 102 may be mounted on an external device. Here, due to the outer connection terminals 102, a crack may occur in the first and second under-bump pads UBP1 and UBP2. When viewed in a plan view, the crack may be formed along a boundary of a contact surface between the first under-bump pad UBP1 and the first outer connection terminal 102a, in the first under-bump pad UBP1, and along a boundary of a contact surface between the second under-bump pad UBP2 and the second outer connection terminal 102b, in the second under-bump pad UBP2.

According to an embodiment of the inventive concept, two regions, which are separated from each other with a vulnerable point in the first and second under-bump pads UBP1 and UBP2 interposed therebetween, may be electrically connected to each other using the first and second patterns 124a and 124b of the second substrate interconnection layer RL2. That is, a bypass may be provided for an electrical connection between the first and second under-bump pads UBP1 and UBP2 and the connection pattern CNP. Thus, even when the first and second under-bump pads UBP1 and UBP2 are damaged (e.g., cracked) depending on positions of the substrate protection layer 130 and the first and second openings OP1 and OP2, an electrical disconnection issue may not occur in the first and second under-bump pads UBP1 and UBP2. That is, it may be possible to provide a wiring substrate with improved structural stability, reliability, and electrical characteristics.

Another portion of the second substrate wiring pattern 124 may vertically penetrate the first substrate insulating pattern 112 and may be coupled to a top surface of the third under-bump pad UBP.

The wiring substrate 100 may further include a third substrate interconnection layer RL3 and substrate pads 104, which are disposed on the second substrate interconnection layer RL2.

The third substrate interconnection layer RL3 may be disposed on the second substrate interconnection layer RL2. The third substrate interconnection layer RL3 may correspond to a pad layer, which is used to mount a semiconductor chip, a semiconductor element, or a semiconductor device on the wiring substrate 100. The third substrate interconnection layer RL3 may include a third substrate insulating pattern 142 and a third substrate wiring pattern 144.

The third substrate wiring pattern 144 may be provided on the second substrate insulating pattern 122. The third substrate wiring pattern 144 on the second substrate insulating pattern 122 may extend horizontally. The third substrate wiring pattern 144 may be provided on a top surface of the second substrate insulating pattern 122. The third substrate wiring pattern 144 may protrude to a region on the top surface of the second substrate insulating pattern 122. The third substrate wiring pattern 144 may include a conductive material. For example, the third substrate wiring pattern 144 may include a metallic material (e.g., copper (Cu)).

The third substrate wiring pattern 144 may have a damascene structure. For example, a portion of the third substrate wiring pattern 144 may be used as a horizontal wire, which is horizontally extended on the top surface of the second substrate insulating pattern 122, and another portion of the third substrate wiring pattern 144 may be a vertical wire, which extends from the horizontal wire to vertically penetrate the second substrate insulating pattern 122 and is coupled to the second substrate wiring pattern 124.

The third substrate insulating pattern 142 may be disposed on the second substrate insulating pattern 122. The third substrate insulating pattern 142 may cover the third substrate wiring pattern 144, on the top surface of the second substrate insulating pattern 122. The third substrate insulating pattern 142 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers. Alternatively, the third substrate insulating pattern 142 may include an insulating material. For example, the third substrate insulating pattern 142 may include silicon oxide (SiO), silicon nitride (SiN), silicon oxynitride (SiON) or insulating polymer.

The substrate pads 104 may be disposed on the third substrate insulating pattern 142. At least a portion of each of the substrate pads 104 may vertically penetrate the third substrate insulating pattern 142 and may be coupled to the third substrate wiring pattern 144. In other embodiments, in contrast to the illustrated structure, the substrate pads 104 may not be provided. In this case, the third substrate insulating pattern 142 may have openings exposing the third substrate wiring pattern 144, and portions of the third substrate wiring pattern 144 exposed by the openings may be used as substrate pads of the wiring substrate 100. The substrate pads 104 may include a conductive material. For example, the substrate pads 104 may include a metallic material (e.g., copper (Cu)).

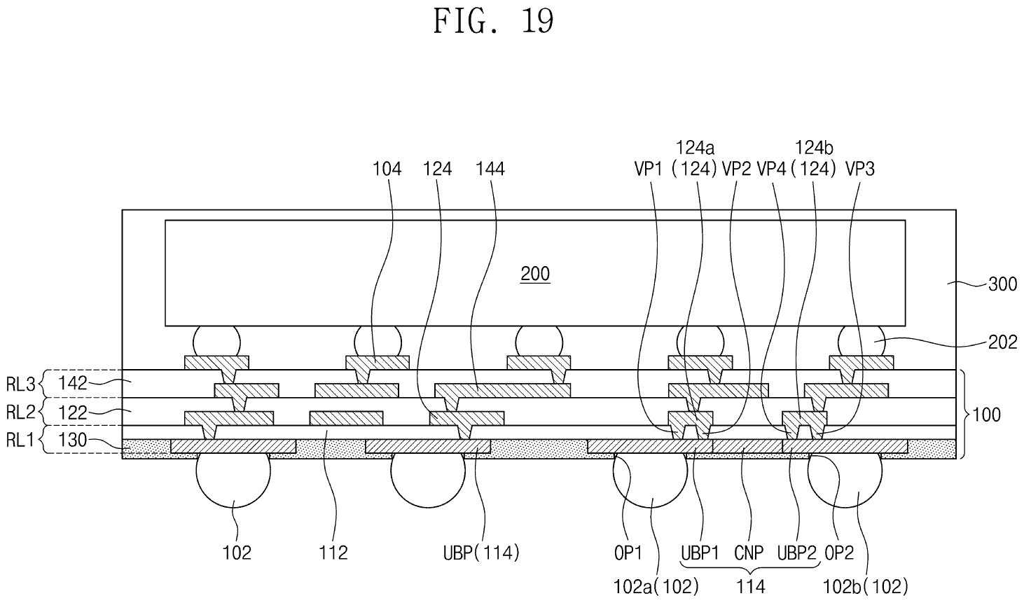

FIG. 19 is a sectional view illustrating a semiconductor package according to an embodiment of the inventive concept.

Referring to FIG. 19, the wiring substrate 100 may be provided. The wiring substrate 100 may correspond to the wiring substrate 100 described with reference to FIGS. 1 to 19.

A semiconductor chip 200 may be provided on the wiring substrate 100. The semiconductor chip 200 may be a logic chip or a memory chip. However, the inventive concept is not limited to this example, and the semiconductor chip 200 may include a logic chip, a memory chip, a semiconductor chip including various integrated device, or a passive device. A bottom surface of the semiconductor chip 200 may be an active surface, and a top surface of the semiconductor chip 200 may be an inactive surface. That is, the semiconductor chip 200 may be disposed on the wiring substrate 100 in a face down manner.

The semiconductor chip 200 may be mounted on the wiring substrate 100. For example, the semiconductor chip 200 may be mounted on the wiring substrate 100 in a flip chip manner. In detail, the semiconductor chip 200 may be electrically connected to the wiring substrate 100 through chip connection terminals 202. The chip connection terminals 202 may be provided between chip pads of the semiconductor chip 200 and the substrate pads 104 of the wiring substrate 100. FIG. 19 illustrates an example, in which the semiconductor chip 200 is mounted on the wiring substrate 100 in a flip chip manner, but the inventive concept is not limited to this example. For example, the semiconductor chip 200 may be mounted on the wiring substrate 100 in a wire bonding manner.

A mold layer 300 may be provided on the wiring substrate 100. The mold layer 300 on the wiring substrate 100 may cover the semiconductor chip 200. The mold layer 300 may include an insulating material. For example, the mold layer 300 may include an insulating polymer material (e.g., an epoxy molding compound (EMC)).

In a wiring substrate according to an embodiment of the inventive concept, a pattern of a second substrate interconnection layer may be used as a bypass for an electrical connection between under-bump pads and a connection pattern. Thus, by using the patterns of the second substrate interconnection layer, it may be possible to stably maintain the electrical connection between the under-bump pads and the connection pattern, even when a crack or damage occurs in the under-bump pads depending on a substrate protection layer and openings. That is, it may be possible to provide a wiring substrate with improved structural stability, reliability, and electrical characteristics. Via portions may be disposed to be adjacent to a boundary between the under-bump pads and the connection pattern. That is, it may be possible to reduce a length of the electrical path between the under-bump pads and the connection pattern through the patterns of the second substrate interconnection layer.

Two regions, which are separated from each other with a vulnerable point in the under-bump pad interposed therebetween, may be electrically connected to each other using the pattern of the second substrate interconnection layer. That is, a bypass may be provided for an electrical connection between the under-bump pads and the connection pattern. Thus, even when the under-bump pads are damaged depending on positions of the substrate protection layer and the openings, an electrical disconnection issue may not occur in the under-bump pads. That is, it may be possible to provide a wiring substrate with improved structural stability, reliability, and electrical characteristics.

While example embodiments of the inventive concept have been particularly shown and described, it will be understood by one of ordinary skill in the art that variations in form and detail may be made therein without departing from the scope of the attached claims.

1. A wiring substrate, comprising:
a first interconnection layer;
a second interconnection layer on the first interconnection layer; and
a substrate protection layer on a bottom surface of the first interconnection layer opposite the second interconnection layer,
wherein the first interconnection layer comprises:
a first under-bump pad; and
a first wiring pattern that is connected to the first under-bump pad and extends from the first under-bump pad in a first direction,
wherein the second interconnection layer comprises:
a first via portion coupled to a top surface of the first under-bump pad and extending in a second direction that is perpendicular to the first direction;
a second via portion coupled to a top surface of the first wiring pattern and extending in the second direction; and
a second wiring pattern that is on the first and second via portions and is electrically connected to the first and second via portions,
wherein the substrate protection layer includes a first opening exposing a bottom surface of the first under-bump pad opposite the second interconnection layer,
the first via portion is overlaps with the first opening in the second direction, and
the second via portion is laterally spaced apart from the first opening.

2. The wiring substrate of claim 1, wherein the first via portion comprises a plurality of first via portions that are coupled to the top surface of the first under-bump pad and overlap with the first opening in the second direction, and
the second via portion is spaced apart from the first opening in the first direction.

3. The wiring substrate of claim 2, wherein the first via portions are arranged in a cross shape, a line shape, or a ring shape, in plan view.

4. The wiring substrate of claim 2, wherein adjacent ones of the first via portions are laterally spaced apart from each other by a same distance.

5. The wiring substrate of claim 1, wherein the first via portion is offset toward the first wiring pattern, relative to a center of the first under-bump pad.

6. The wiring substrate of claim 1, wherein the second wiring pattern laterally extends from the first via portion on the first under-bump pad to the second via portion on the first wiring pattern.

7. The wiring substrate of claim 1, wherein the first under-bump pad and the first wiring pattern comprise a same material and form a unitary member.

8. The wiring substrate of claim 1, wherein the first interconnection layer further comprises a second under-bump pad, which is spaced apart from the first under-bump pad in the first direction and is connected to the first wiring pattern,
wherein the second interconnection layer further comprises:
a third via portion coupled to a top surface of the second under-bump pad and extending in the second direction;
a fourth via portion coupled to the top surface of the first wiring pattern and extending in the second direction; and
a third wiring pattern that is on the third and fourth via portions and is electrically connected to the third and fourth via portions,
wherein the substrate protection layer includes a second opening exposing a bottom surface of the second under-bump pad,
the third via portion overlaps with the second opening in the second direction, and
the fourth via portion is laterally spaced apart from the second opening.

9. The wiring substrate of claim 8, wherein the second via portion is on the top surface of the first wiring pattern adjacent to the first opening, and
the fourth via portion is on the top surface of the first wiring pattern adjacent to the second opening.

10. The wiring substrate of claim 1, wherein the first and second via portions and the second wiring pattern comprise a same material and form a unitary member.

11. The wiring substrate of claim 1, further comprising:
an outer terminal that is in the first opening and is coupled to the bottom surface of the first under-bump pad,
wherein the first under-bump pad comprises a crack therein that is between the first via portion and the second via portion in plan view, and
wherein the first under-bump pad and the first wiring pattern are electrically connected to each other through the first and second via portions.

12. A wiring substrate, comprising:
a first interconnection layer;
a second interconnection layer on the first interconnection layer; and
a substrate protection layer on a bottom surface of the first interconnection layer opposite the second interconnection layer,
wherein the first interconnection layer comprises:
a first under-bump pad;
a second under-bump pad laterally spaced apart from the first under-bump pad; and
a first wiring pattern extending between the first under-bump pad and the second under-bump pad,
wherein the substrate protection layer includes a first opening exposing a bottom surface of the first under-bump pad opposite the second interconnection layer and a second opening exposing a bottom surface of the second under-bump pad opposite the second interconnection layer,
wherein the second interconnection layer comprises:
a first via portion coupled to a top surface of the first under-bump pad;
a second via portion adjacent to the first opening and coupled to a top surface of the first wiring pattern;
a third via portion coupled to a top surface of the second under-bump pad; and
a fourth via portion adjacent to the second opening and coupled to the top surface of the first wiring pattern,
wherein the first under-bump pad and the first wiring pattern are electrically connected to each other through the first and second via portions, and
wherein the second under-bump pad and the first wiring pattern are electrically connected to each other through the third and fourth via portions.

13. The wiring substrate of claim 12, wherein, in plan view,
the first via portion overlaps with the first opening,
the second via portion is spaced apart from the first opening,
the third via portion overlaps with the second opening, and
the fourth via portion is spaced apart from the second opening.

14. The wiring substrate of claim 12, wherein the second interconnection layer further comprises:
a second wiring pattern on and electrically connected to the first and second via portions; and
a third wiring pattern on and electrically connected to the third and fourth via portions.

15. The wiring substrate of claim 14, wherein the first and second via portions and the second wiring pattern comprise a same material and form a unitary member, and
the third and fourth via portions and the third wiring pattern comprise a same material and form a unitary member.

16. The wiring substrate of claim 12, wherein the first wiring pattern directly contacts the first under-bump pad and the second under-bump pad.

17. The wiring substrate of claim 16, wherein the first and second under-bump pads and the first wiring pattern comprise a same material and form a unitary member.

18. The wiring substrate of claim 12, wherein the first via portion comprises a plurality of first via portions, and the third via portion comprises a plurality of third via portions,
wherein the first via portions are coupled to the top surface of the first under-bump pad and overlap the first opening in plan view, and
wherein the third via portions are coupled to the top surface of the second under-bump pad and overlap the second opening in plan view.

19. (canceled)

20. (canceled)

21. The wiring substrate of claim 12, further comprising:
an outer terminal that is in the first opening and is coupled to the bottom surface of the first under-bump pad, or is in the second opening and is coupled to the bottom surface of the second under-bump pad,
wherein the first under-bump pad comprises a crack therein that is between the first via portion and the second via portion, or the second under-bump pad comprises a crack therein that is between the third via portion and the fourth via portion, in plan view.

22. A semiconductor package, comprising:
a substrate;
a semiconductor chip on the substrate; and
first and second outer terminals on a bottom surface of the substrate,
wherein the substrate comprises:
a first under-bump pad and a second under-bump pad on the bottom surface of the substrate;
a first wiring pattern on the bottom surface of the substrate that connects the first under-bump pad to the second under-bump pad;
a second wiring pattern on the first under-bump pad and extending onto the first wiring pattern;
a third wiring pattern on the second under-bump pad and extending onto the first wiring pattern;
a first via portion and a second via portion extending from a bottom surface of the second wiring pattern; and
a third via portion and a fourth via portion extending from a bottom surface of the third wiring pattern,
wherein the first outer terminal is coupled to the first under-bump pad,
wherein the second outer terminal is coupled to the second under-bump pad, and
wherein, in plan view,
the first via portion overlaps with the first outer terminal and is coupled to the first under-bump pad,
the second via portion is laterally spaced apart from the first outer terminal and is coupled to the first under-bump pad,
the third via portion overlaps with the second outer terminal and is coupled to the second under-bump pad, and
the fourth via portion is laterally spaced apart from the second outer terminal and is coupled to the second under-bump pad.

23-28. (canceled)
